(19) United States
(12) Patent Application Publication
(10) Pub. No.: US 2005/0236630 A1
(43) Pub. Date: Oct. 27, 2005

(54) Transparent contact for light emitting diode

(76) Inventor: Wang-Nang Wang, Tai Chung City (TW)

Correspondence Address: GLENN PATENT GROUP, 3475 EDISON WAY, SUITE L, MENLO PARK, CA, 94025, US

(21) Appl. No.: 10/831,507

(22) Filed: Apr. 23, 2004

(51) Int. Cl. H01L 27/15; H01L 31/12; H01L 33/00

(52) U.S. Cl. 257/80

(57) ABSTRACT

A transparent conductive film is deposited between the electrode and semiconductor diode to spread the current evenly, reduce the series resistance and increase light transmittance at certain wavelength. ZnO film can be used as the transparent conductive film. The Ni/Au/ZnO film is found to have an increased light transmission compared with an annealed Ni/Au contact. The maximum optical transmission measured through the Ni/Au/ZnO film is 90%.

### BACKGROUND

1. Field of Invention

The present invention relates to a transparent contact for light emitting diodes. More particularly, the present invention relates to a transparent contact for gallium nitride-based light emitting diodes.

2. Description of Related Art

In recent years, GaN-based semiconductors have become increasingly attractive as material for high power optoelectronic devices in the blue and violet region of the visible spectrum. These devices require electrodes with low specific contact resistance (SCR) for current injection and thus considerable effort has been devoted to developing low resistance contacts for GaN. For surface emitting devices, another important consideration is the optical transparency of the contact, at the wavelength of the emitted radiation.

Many reports demonstrate low SCR for contacts on n-GaN using metal or Si implantation of the GaN. The reports also indicate the existence of fewer problems in achieving a low SCR for contacts on n-type GaN, compared with p-type GaN.

Because of the low carrier concentration and high work function of p-GaN, it is rather more difficult to achieve an ohmic contact with a low SCR. To date, thin Ni/Au films have been the most commonly used contacts on p-GaN for GaN-based LEDs, where the optimum annealing conditions were found to be an annealing temperature of 500° C. in an oxygen atmosphere.

FIG. 1 illustrates a conventional light emitting diode design of Nichia Chemical Industries. Au/Ni film 110 is used as a current spreading layer for p-GaN layer 12 in the LED. However, nonuniform resistivity distribution and rough surface are found after annealing Au/Ni film 110. Forming a good ohmic contact between Au/Ni film 110 and p-GaN layer 12 is difficult. Other metals, e.g., Pt, Ta/Ti, and Pd/Au, have shown comparable SCR values to those of Ni/Au. Thus, the development of a contact with a low SCR, which is optically transparent to the wavelength of light generated by the light emitting diodes, is an important consideration when fabricating GaN-based surface emitting LEDs.

### SUMMARY

It is therefore an objective of the present invention to provide a enhanced transparent contact for gallium nitride-based light emitting diodes.

In accordance with the foregoing and other objectives of the present invention, a light emitting diode with an ZnO transparent contact is provided. A transparent insulating material, including sapphire (Al₂O₃), lithium-gallium oxide (LiAlO₂), lithium-aluminum oxide (LiGaO₂), and spinal (MgAl₂O₄), serves as a substrate. A buffer layer (n-GaN), a lower cladding layer (n-AlGaN), a light emitting layer (u-InGaN), an upper cladding layer (p-AlGaN), and a contact layer (p-GaN) are sequentially deposited on the substrate. Subsequently, a thin metal layer, deposited on the contact layer (p-GaN), serves as a contact layer. This thin metal layer can be a Ni/Au, Ni/Cr, Pt, and Ta layer. A transparent ZnO layer, formed on the thin metal layer, serves as a current spreading and anti-reflection layer. A first electrode is formed on a partially exposed area of the buffer layer (n-GaN) and a second electrode is formed on the top of the transparent ZnO layer. An additional anti-reflection layer is coated on the top of the transparent ZnO layer so that more light can be extracted from the device. The anti-reflection layer material can be SiO₂, Al₂O₃, TiO₂, Si₃N₄, ZnS, or CaF₂.

According to another preferred embodiment of present invention, a light emitting diode with a ZnO transparent contact is provided. An n-type silicon carbide semiconductor layer serves as a substrate. The substrate material can also be gallium (GaAs), silicon (Si) or n-type ZnO. A buffer layer (n-GaN), a lower cladding layer (n-AlGaN), a light emitting layer (u-InGaN), an upper cladding layer (p-AlGaN), and a contact layer (p-GaN) are sequentially deposited on the substrate. Subsequently, a thin metal layer, deposited on the contact layer (p-GaN), serves as a contact layer. This thin metal layer can be a Ni/Au, Ni/Cr, Pt, and Ta layer. A transparent ZnO layer, formed on the thin metal layer, serves as a current spreading and anti-reflection layer. A first electrode is formed underneath the substrate and a second electrode is formed on the top of the transparent ZnO layer. Besides the electrode, an additional anti-reflection layer is coated on the top of the transparent ZnO layer so that more light can be extracted from the device. The anti-reflection layer material can be SiO₂, Al₂O₃, TiO₂, Si₃N₄, ZnS, or CaF₂.

As embodied and broadly described herein, the invention provides a highly transparent Ni/Au/ZnO. The light transmittance is 87%-90% at wavelengths in the range 450 nm-500 nm. Light extraction is 15% higher than that with a Ni/Au layer.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 illustrates a conventional light emitting diode design as manufactured by Nichia Chemical Industries;

FIG. 2A illustrates a light emitting diode design with a ZnO transparent contact according to one preferred embodiment of this invention;

FIG. 2B illustrates a light emitting diode design with a ZnO transparent contact and an anti-reflection layer according to one preferred embodiment of this invention;

FIG. 3A illustrates a light emitting diode design with a ZnO transparent contact according to another preferred embodiment of this invention;

FIG. 3B illustrates a light emitting diode design with a ZnO transparent contact and an anti-reflection layer according to another preferred embodiment of this invention; and

FIG. 4 illustrates the simulated and experimental results for Ni/Au and Ni/Au/ZnO layer according to yet another preferred embodiment of this invention.

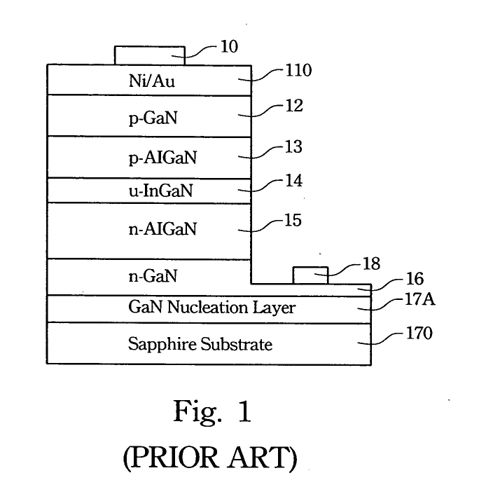

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

In order to spread the current evenly, reduce the series resistance and increase light transmittance at certain wavelength, a transparent conductive film is deposited between a semiconductor diode and its electrode. Zinc Oxide (ZnO) can be used as the transparent conductive film, which is particularly applicable to a GaN-based light emitting diode.

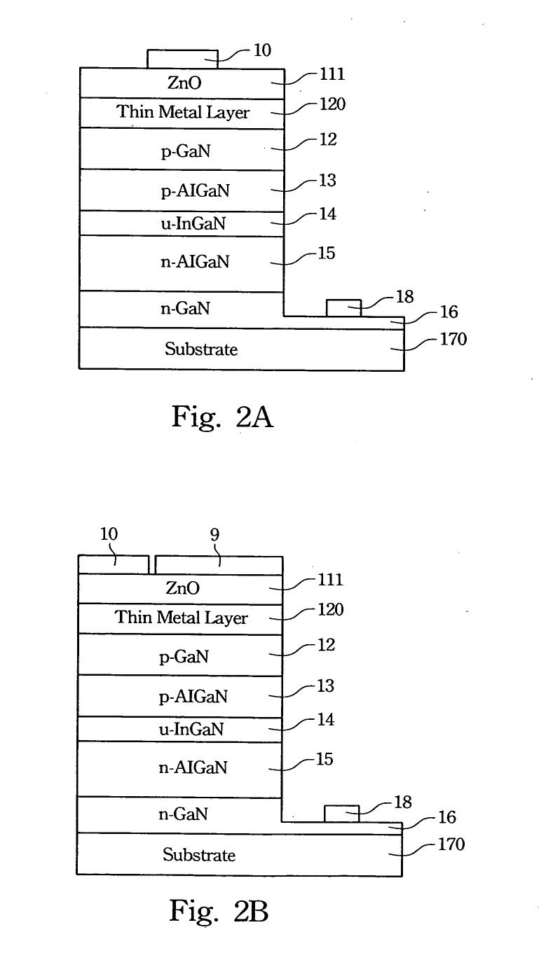

FIG. 2A illustrates a light emitting diode design with a ZnO transparent contact according to one preferred embodiment of this invention. A transparent insulating material, including sapphire (Al₂O₃), lithium-gallium oxide (LiAlO₂), lithium-aluminum oxide (LiGaO₂), and spinal (MgAl₂O₄), serves as a substrate 170. A buffer layer (n-GaN) 16, a lower cladding layer (n-AlGaN) 15, a light emitting layer (u-InGaN) 14, an upper cladding layer (p-AlGaN) 13, and a contact layer (p-GaN) 12 are sequentially deposited on the substrate 170. Subsequently, a thin metal layer 120, deposited on the contact layer (p-GaN) 12, serves as a contact layer. This thin metal layer 120 can be a Ni/Au, Ni/Cr, Pt, and Ta layer. A transparent ZnO layer 111, formed on the thin metal layer 120, serves as a current spreading and anti-reflection layer. A first electrode 18 is formed on a partially exposed area of the buffer layer (n-GaN) 16 and a second electrode 10 is formed on the top of the transparent ZnO layer 111.

FIG. 2B illustrates a light emitting diode design with a ZnO transparent contact and an anti-reflection layer according to one preferred embodiment of this invention. A transparent insulating material, including sapphire (Al₂O₃), lithium-gallium oxide (LiAlO₂), lithium-aluminum oxide (LiGaO₂), and spinal (MgAl₂O₄), serves as a substrate 170. A buffer layer (n-GaN) 16, a lower cladding layer (n-AlGaN) 15, a light emitting layer (u-InGaN) 14, an upper cladding layer (p-AlGaN) 13, and a contact layer (p-GaN) 12 are sequentially deposited on the substrate 170. Subsequently, a thin metal layer 120, deposited on the contact layer (p-GaN) 12, serves as a contact layer. This thin metal layer 120 can be Ni/Au, Ni/Cr, Pt, or Ta layer. A transparent ZnO layer 111, formed on the thin metal layer 120, serves as a current spreading and anti-reflection layer. A first electrode 18 is formed on a partially exposed area of the buffer layer (n-GaN) 16 and a second electrode 10 is formed on the top of the transparent ZnO layer 111. Besides the electrode 10, an additional anti-reflection layer 9 is coated on the top of the transparent ZnO layer 111 so that more light can be extracted from the device. The anti-reflection layer material can be SiO₂, Al₂O₃, TiO₂, Si₃N₄, ZnS, or CaF₂.

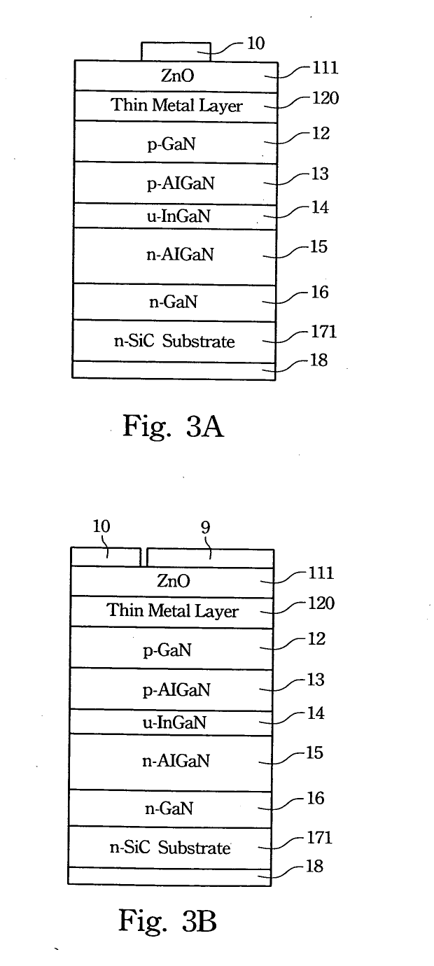

FIG. 3A illustrates a light emitting diode design with a ZnO transparent contact according to another preferred embodiment of this invention. An n-type silicon carbide semiconductor layer 171 serves as a substrate. The substrate material can also be gallium (GaAs), silicon (Si) or n-type ZnO. A buffer layer (n-GaN) 16, a lower cladding layer (n-AlGaN) 15, a light emitting layer (u-lnGaN) 14, an upper cladding layer (p-AlGaN) 13, and a contact layer (p-GaN) 12 are sequentially deposited on the substrate 171. Subsequently, a thin metal layer 120, deposited on the contact layer (p-GaN) 12, serves as a contact layer. This thin metal layer 120 can be Ni/Au, Ni/Cr, Pt, and Ta layer. A transparent ZnO layer 111, formed on the thin metal layer 120, serves as a current spreading and anti-reflection layer. A first electrode 18 is formed underneath the substrate 171 and a second electrode 10 is formed on the top of the transparent ZnO layer 111.

FIG. 3B illustrates a light emitting diode design with a ZnO transparent contact and a anti-reflection layer according to another preferred embodiment of this invention. An n-type silicon carbide semiconductor layer serves as a substrate 171. The substrate material can also be gallium (GaAs), silicon (Si) or n-type ZnO. A buffer layer (n-GaN) 16, a lower cladding layer (n-AlGaN) 15, a light emitting layer (u-lnGaN) 14, an upper cladding layer (p-AlGaN) 13, and a contact layer (p-GaN) 12 are sequentially deposited on the substrate 171. Subsequently, a thin metal layer 120, deposited on the contact layer (p-GaN) 12, serves as a contact layer. This thin metal layer 120 can be Ni/Au, Ni/Cr, Pt, and Ta layer. A transparent ZnO layer 111, formed on the thin metal layer 120, serves as a current spreading and anti-reflection layer. A first electrode 18 is formed underneath the substrate 171 and a second electrode 10 is formed on the top of the transparent ZnO layer 111. Besides the electrode 10, an additional anti-reflection layer 9 is coated on the top of the transparent ZnO layer 111 so that more light can be extracted from the device. The anti-reflection layer material can be SiO₂, Al₂O₃, TiO₂, Si₃N₄, ZnS, or CaF₂.

Note that n-type mentioned above is the first conductivity type while p-type mentioned above is the second conductivity type.

An investigation of the ZnO layer growth demonstrates a high value for light transmittance (90%) with a reasonable resistivity (1.6×10⁻³ Ωcm²). Because the Ni/Au layer has to be annealed in order to obtain a lower specific contact resistance, there are two methods for the fabrication of the Ni/Au/ZnO layer. The first method is to anneal Ni/Au/ZnO layers at 500° C. for 5 minutes in N2. One quick examination of this method is conducted. The ZnO layer is cracked after annealing because rounded grains with a typical size of 20 nm are formed on Ni/Au layer. Hence, this formation of rough surface will crack the ZnO layer on the top of the Ni/Au layer. The alternative method is to first anneal the Ni/Au layer and then deposit ZnO layer on this annealed the Ni/Au layer. The following embodiment is based on this process for the fabrication of Ni/Au/ZnO electrode for p-GaN.

Ni/Au=5 nm/5 nm is deposited on p-GaN by thermal evaporation. According to the Hall measurement, the electron concentration and Hall mobility of this p-GaN are 2.2×10¹⁷ cm⁻³ and 11 cm²/Vs, respectively. The specific contact resistance measurement was based on the circular transmission line method (CTLM). After annealing at 500° C. for 5 minutes in N2, an unintentional ZnO layer is deposited on the top of the Ni/Au by use of a dual ion beam sputtering system and a Zn target. The deposition condition is listed in Table 1. The O₂ flow rate of 6 sccm was chosen specifically because a low resistivity (7.7×10⁻³ Ωcm) and a high transmittance (90%) have been achieved for this condition.

TABLE 1
ZnO growth condition for the Ni/Au/ZnO layer.

| Parameter | Value |
|---|---|
| RF Power | 140 W |
| Air Flow Rate (Ion Gun) | 50 sccm |
| Chamber Pressure | 2.1 × 10⁻⁴ Torr |
| Screen Grid Voltage | 500 V |
| Accelerate Grid Voltage | 300 V |
| O₂ | 6 sccm |
| Substrate Temperature | 20° C. |

Because of the ZnO cracking issue, the fabrication process using in above embodiment for Ni/Au/ZnO is proposed and no cracking is found after the ZnO deposition. The suitability for application thereof in light emitting devices is thus demonstrated.

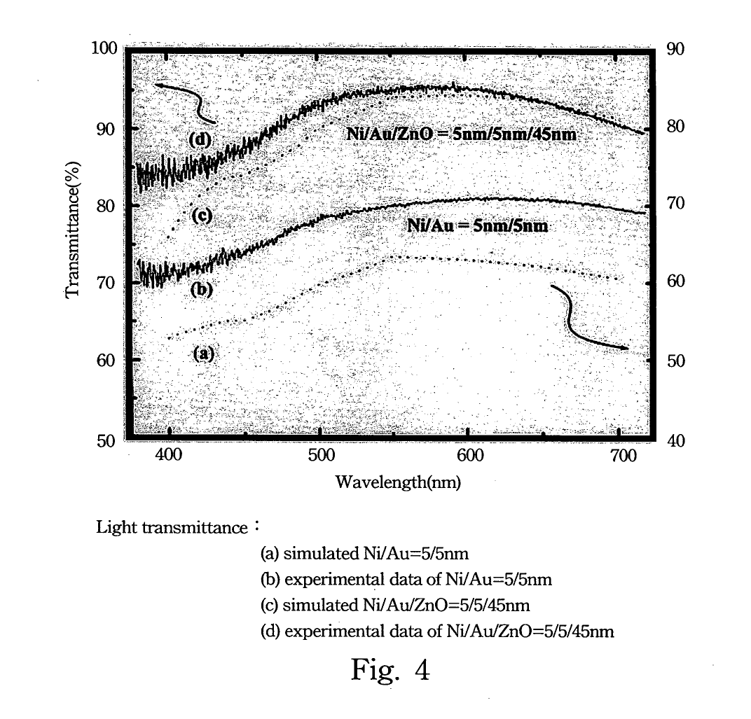

FIG. 4 illustrates the simulated and experimental results for Ni/Au and Ni/Au/ZnO layer according to yet another preferred embodiment of this invention. The dotted lines in FIG. 4 are for simulated data. Note that the transmittance scale has been adjusted for the simulated results in order to demonstrate the close fit of the simulation data. The simulated transmittance for as-grown Ni/Au layers was measured as 57% at a wavelength of 470 nm (FIG. 4(a)), whereas the measured optical transmittance for the annealed Ni/Au layers is 75%, as represented in FIG. 4(b). This increase is mainly due to the change of the surface morphology. After one ZnO layer is deposited on the annealed Ni/Au, the light transmittance increased to 90%, shown in FIG. 4(d). According to the simulation, the improvement made by the addition of the ZnO layer is a 20% increase in the transmittance. However, an improvement in light transmission of 15% was actually achieved with the device according to the invention. It should be noted that the simulation assumed uniform layers of Ni/Au on the p-GaN.

According to preferred embodiments of present invention, a highly transparent Ni/Au/ZnO layer is fabricated and characterized. The light transmittance is 87%-90% at wavelengths in the range of 450 nm-500 nm. Light extraction is 15% higher than that with a Ni/Au layer.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A light emitting diode, comprising:
a transparent insulating substrate;
a first conductive GaN layer, formed on said transparent insulating substrate as a buffer;
a first conductive AlGaN layer, formed on said first conductive GaN layer as a lower cladding layer;
an InGaN lighting emitting layer, formed on said first conductive AlGaN layer;
a second conductive AlGaN layer, formed on said InGaN lighting emitting layer as an upper cladding layer;
a second conductive GaN layer, formed on said second conductive AlGaN layer as a contact layer;
a thin metal layer, formed on said second conductive GaN layer as a contact layer;
a transparent ZnO conductive layer, formed on said thin metal layer as a current spreading and anti-reflection layer;
a first electrode, formed on a partially exposed area of said first conductive GaN layer; and
a second electrode, formed on a top of said transparent ZnO conductive layer.

2. The light emitting diode of claim 1, wherein said thin metal layer is selected from a group consisting of Ni/Au, Ni/Cr, Pt and Ta layers.

3. The light emitting diode of claim 1, wherein said thin metal layer has a thickness of between about 10 and 100 Angstroms.

4. The light emitting diode of claim 1, wherein said transparent insulating substrate is selected from a group consisting of Al₂O₃, LiAlO₂, LiGaO₂, and MgAl₂O₄ substrates.

5. The light emitting diode of claim 1, further comprising a second anti-reflection layer, formed on said transparent ZnO conductive layer.

6. The light emitting diode of claim 5, wherein said anti-reflection layer is selected from a group consisting of SiO₂, Al₂O₃, TiO₂, Si₃N₄, ZnS, and CaF₂ layers.

7. The light emitting diode of claim 5, wherein said thin metal layer is selected from a group consisting of Ni/Au, Ni/Cr, Pt and Ta layers.

8. The light emitting diode of claim 5, wherein said thin metal layer has a thickness of between about 10 and 100 Angstroms.

9. The light emitting diode of claim 5, wherein said transparent insulating substrate is selected from a group consisting of Al₂O₃, LiAlO₂, LiGaO₂, and MgAl₂O₄ substrates.

10. A light emitting diode, comprising:
a first conductivity-type semiconductor layer, serving as a substrate;
a first conductivity-type GaN layer, formed on said first conductivity-type semiconductor layer as a buffer layer;
a first conductivity type-AlGaN layer, formed on said first conductivity type-GaN layer as a lower cladding layer;
an InGaN light emitting layer, formed on said first conductivity type AlGaN layer;
a second conductivity-type AlGaN layer, formed on said InGaN light emitting layer as upper cladding layer;
a second conductivity-type GaN layer, formed on said second conductivity-type AlGaN layer as a contact layer;
a thin metal layer, formed on said second conductive GaN layer as a contact layer;
a transparent ZnO conductive layer, formed on said second conductivity-type GaN layer as a current spreading and anti-reflection layer;
a first electrode, formed underneath said first conductivity-type semiconductor layer; and
a second electrode, formed on the top of said transparent ZnO conductive layer.

11. The light emitting diode of claim 10, wherein said thin metal layer is selected from a group consisting of Ni/Au, Ni/Cr, Pt and Ta layers.

12. The light emitting diode of claim 10, wherein said thin metal layer has a thickness of between about 10 and 100 Angstroms.

13. The light emitting diode of claim 10, wherein said first conductivity-type semiconductor layer is selected from a group consisting of SiC, GaAs, Si and ZnO layers.

14. The light emitting diode of claim 10, further comprising a second anti-reflection layer, formed on said transparent ZnO conductive layer.

15. The light emitting diode of claim 14, wherein said anti-reflection layer is selected from a group consisting of SiO₂, Al₂O₃, TiO₂, Si₃N₄, ZnS, and CaF₂ layers.

16. The light emitting diode of claim 14, wherein said thin metal layer is selected from a group consisting of Ni/Au, Ni/Cr, Pt and Ta layers.

17. The light emitting diode of claim 14, wherein said thin metal layer has a thickness of between about 10 and 100 Angstroms.

18. The light emitting diode of claim 14, wherein said first conductivity-type semiconductor layer is selected from a group consisting of SiC, GaAs, Si and ZnO layers.
